(19) United States
(12) Patent Application Publication
(10) Pub. No.: US 2025/0223795 A1
(43) Pub. Date: Jul. 10, 2025

(54) Robotic Assisted Exterior Insulated Finish System and Method

(71) Applicant: FunForm, LLC, Westport, CT (US)

(72) Inventors: Michele Knapp, Glastonbury, CT (US); Christopher J. Knapp, Salt Lake City, UT (US)

(21) Appl. No.: 18/854,960

(22) PCT Filed: Apr. 5, 2023
(86) PCT No.: PCT/US2023/065382

§ 371 Date: Oct. 7, 2024

Related U.S. Application Data
(60) Provisional application No. 63/327,760, filed on Apr. 5, 2022.

(51) Int. Cl. E04B 1/76; B26D 5/00; B26F 3/12; E06B 1/28; G06F 30/12; G06T 17/00

(52) U.S. Cl. CPC E04B 1/7629; E06B 1/28; G06F 30/12; G06T 17/00; B26D 5/005; B26F 3/12; G06T 2210/04

(57) ABSTRACT

A device may include an inner cassette body, the inner cassette body defining an opening configured to receive a window unit. A device may include a slop positioned around an interior surface of the inner cassette body on a building side of the window cassette, the stop configured to abut an interior surface of the window unit placed in the inner cassette body from an exterior side. A device may include an outer cassette body coupled with a front side of the inner cassette body, the outer cassette body configured to hold a retaining clip, the retaining clip configured to hold the window unit in the inner cassette body against the stop. A device may include a building connection flange positioned around an exterior surface of the inner cassette body, the building connection flange configured to allow the window cassette to be affixed to a building exterior.

### CROSS REFERENCE TO RELATED APPLICATIONS

This application claims priority, under 35 U.S.C. § 119, of U.S. Provisional Patent Application No. 63/327,760, filed Apr. 5, 2022 and titled “Robotic Assisted Exterior Insulated Finish Systems—RAEIFS,” which is incorporated by reference in its entirety.

### BACKGROUND

The present disclosure relates to applying exterior insulated finish systems (EIFS).

The current method of applying EIFS is a multi-step, temperature reliant, one-off, labor intensive process using cost burdened products. EIFS are well known in the industry and per the EIFS Manufacturers Association, if properly maintained can last the life of the building. Most EIFS use expanded polystyrene (EPS) foam as an insulating substrate on the exterior of building walls. This substrate is then covered with reinforced mesh and layers of cementitious coatings which provide a protective and aesthetic finish. In the report “Evaluating an Exterior Insulation and Finish System for Deep Energy Retrofits”, a case study of a 2,300 sq. ft. single family house showed that a “post-retrofit enclosure air tightness of 2 ACH50 was achieved compared to the 15 ACH50 pre-retrofit case” additionally using “BEopt modeled annual energy and utility bill savings were shown with annualized utility bill savings are $1,028; source energy savings are 141.9 MMBtu/year.” Carbon dioxide (CO₂) emission reductions are 8.6 metric tons/year.” In addition to energy savings, occupants of buildings that have been retrofitted with EIFS enjoy increased thermal and acoustic comfort.

EPS foam is expanded in large blocks of approximately 4′ thick (t)×4′ wide (w)×18′ length (1). However, to accommodate current shipping, distribution, and installation practices the blocks are cut down to a small format, typically 24″ w×48″ 1×2″ t, which leads to increased installation times and material costs.

EIFS product manufacturers contract with foam expanders to expand, cut, brand, package and ship boards to building material distributors. Distributors sell to installers and ship material to the job site. Three markups and two trips to get material to the install site.

Once onsite, the small boards are individually scribed to accommodate variances in the façade, penetrations, and projections. Examples include plumbing pipes and standoffs, electrical outlets, lighting, windows, doors, balconies, signage, fire escapes, and architectural details. Once scribed, each board is attached to the building with an expensive adhesive which requires a minimum of 40-degree Fahrenheit air and surface temperature to cure. In the Northeast and other similar climates that have a cold season, this limits the install season to March through October.

For climate Zones 4-6, a minimum R30 is recommended for panelized envelopes retrofits. To achieve that high of an R value using field-installed EIFS, multiple EPS boards need to be layered. If an installer wishes to use a board thicker than 4 inches, they must secure the EIFS product manufacturer's approval in writing.

Flashing details for windows, doors and other penetrations are one-offs, developed for each project and typically worked out onsite by the project architect, installer, and EIFS product manufacturer's technical representatives. Additionally, attaching the insulation boards to the building and forming the window trim and flashing is the most time-consuming step of an EIFS installation.

Further, window retrofits in current EIFS solutions cause disturbance to tenants of the building since they require work from the interior of the building. In some instances, asbestos and lead remediation cause additional disturbance or require window frames to be left in place and replacement sashes to be inserted in the frame, which leads to a less energy efficient end product.

Lack of standardization can result in system failure due to poor detailing at joints, windows, doors, and utility penetrations. Without single party responsibility, when failure occurs each party blames the others. This concept, referred to as “by others” is a recurring theme in construction and is indicative of liability concerns preventing innovation.

### SUMMARY

In some aspects, the techniques described herein relate to a window cassette including: an inner cassette body, the inner cassette body defining an opening configured to receive a window unit; a stop positioned around an interior surface of the inner cassette body on a building side of the window cassette, the stop configured to abut an interior surface of the window unit placed in the inner cassette body from an exterior side; an outer cassette body coupled with a front side of the inner cassette body, the outer cassette body configured to hold a retaining clip, the retaining clip configured to hold the window unit in the inner cassette body against the stop; and a building connection flange positioned around an exterior surface of the inner cassette body, the building connection flange configured to allow the window cassette to be affixed to a building exterior.

In some aspects, the techniques described herein relate to a window cassette, further including: a retaining clip seating channel defined by a protrusion from the front side of the inner cassette body and an interior surface of the outer cassette body; and a retaining clip securing channel on an interior surface of the outer cassette body.

In some aspects, the techniques described herein relate to a window cassette, wherein the retaining clip further includes: a bottom plate, the bottom plate configured to fit in the interior surface of the outer cassette body having a securing ridge configured to couple with the retaining clip securing channel; a window retention member protruding from a top side of the bottom plate and configured to extend beyond the interior surface of the inner cassette body to retain the window unit in the window cassette; and a seating ridge protruding from the bottom plate and configured to couple with the retaining clip seating channel.

In some aspects, the techniques described herein relate to a window cassette, wherein the retaining clip further includes: a drip edge coupled with the window retention member, the drip edge configured to direct water away from the window unit.

In some aspects, the techniques described herein relate to a window cassette, wherein the inner cassette body, the building connection flange, and the outer cassette body are filled with insulating foam.

In some aspects, the techniques described herein relate to a window cassette, wherein the retaining clip includes a mitered edge.

In some aspects, the techniques described herein relate to a method including: performing, by a data capture device, a first scan of an exterior wall of a building; processing, by a panel builder module, first scan data from the data capture device to generate a first panel layout; performing, by the data capture device, a second scan of the exterior wall of the building, the second scan performed to capture data reflecting modifications made to the exterior wall of the building based on analysis of the first scan; creating, by the panel builder module, a second panel layout, the second panel layout including a second plurality of negative volumes based on the second scan; and fabricating, by a panel shaping tool, an EIFS panel based on the second panel layout.

In some aspects, the techniques described herein relate to a method, wherein the data capture device includes a plurality of sensors.

In some aspects, the techniques described herein relate to a method, wherein the plurality of sensors include a LiDAR sensor, a photo sensor, a thermal imaging sensor, and a surface penetrating imaging sensor.

In some aspects, the techniques described herein relate to a method, wherein processing the first scan data further includes: creating, by the panel builder module, a three-dimensional point cloud of the exterior wall of the building using the first scan data; rendering, by the panel builder module, a model of the exterior wall of the building using the three-dimensional point cloud; creating, by the panel builder module, a master volume for creating the first panel layout; creating, by the panel builder module, a first plurality of negative volumes in the master volume corresponding to features of the exterior wall of the building; and generating, by the panel builder module, the first panel layout on the master volume.

In some aspects, the techniques described herein relate to a method, wherein creating the second panel layout includes: identifying, by the panel builder module, a location of a locating pin installed on the exterior wall of the building; identifying, by the panel builder module, a location of a window cassette installed on the exterior wall of the building; and creating, by the panel builder module, the second plurality of negative volumes corresponding to the location of the locating pin and the location of the window cassette.

In some aspects, the techniques described herein relate to a method, wherein fabricating the EIFS panel includes: cutting, by the panel shaping tool, the EIFS panel from a foam billet; and cutting, by the panel shaping tool, a plurality of voids and a plurality of recesses in the EIFS panel based on the first plurality of negative volumes and the second plurality of negative volumes.

In some aspects, the techniques described herein relate to a method, further including: fastening the EIFS panel to the exterior wall of the building by: aligning a recess corresponding to the locating pin with the locating pin; drilling a hole in the exterior wall of the building through a pre-drilled fastener hole in the EIFS panel; and securing the EIFS panel to the exterior wall of the building with a fastener inserted through the pre-drilled fastener hole.

In some aspects, the techniques described herein relate to an EIFS panel including: a foam body; a pre-drilled fastener hole extending through the foam body, the pre-drilled fastener hole configured to align a fastener with a support structure of a building, wherein, when the fastener is inserted through the pre-drilled fastener hole, the EIFS panel is secured to the support structure of the building; and a first recess in a building facing surface of the foam body, the first recess configured to couple with a locating node affixed to an exterior wall of a building, wherein the coupling of the recess and the locating node aligns the pre-drilled fastener hole with the support structure of the building and supports the foam body while the fastener is attached to the support structure of the building.

In some aspects, the techniques described herein relate to a EIFS panel, further including: a second recess in the building facing surface of the foam body, the second recess configured to align with a feature on the exterior wall of the building, such that the foam body sits flush with the exterior wall of the building.

In some aspects, the techniques described herein relate to a EIFS panel, further including: a first void cut through the foam body, the first void configured to align with a window cassette attached to the exterior wall of the building; and a third recess in the building facing surface of the foam body surrounding the void, the third recess configured to fit over a flange of the window cassette.

In some aspects, the techniques described herein relate to a EIFS panel, further including: a drainage groove in the building facing surface of the foam body.

In some aspects, the techniques described herein relate to a EIFS panel, further including: a foam attachment anchor secured in the pre-drilled fastener hole, the foam attachment anchor configured to couple the fastener with the foam body.

In some aspects, the techniques described herein relate to a EIFS panel, further including: a second void cut through the foam body, the second void configured to align with a mounting block attached to the exterior wall of the building.

In some aspects, the techniques described herein relate to a EIFS panel, wherein the foam body includes a graphite enhanced polystyrene insulation board.

However, this list of features and advantages is not all-inclusive and many additional features and advantages are within the scope of the present disclosure. Moreover, it should be noted that the language used in the present disclosure has been principally selected for readability and instructional purposes, and not to limit the scope of the subject matter disclosed herein.

### BRIEF DESCRIPTION OF THE DRAWINGS

FIG. 1 is a block diagram illustrating an example system for building EIFS panels.

FIG. 2 is a flowchart of an example EIFS installation method according to the techniques described herein.

FIG. 3 depicts an example data capture device, according to one embodiment.

FIG. 4 is a flowchart of an example method for processing scan data using panel builder software.

FIG. 5 depicts an example wall for an EIFS installation.

FIG. 6 depicts an example three-dimensional rendering of a wall using scan data.

FIG. 7 depicts an example of negative volumes created in a master volume.

FIG. 8 depicts an example panel layout.

FIG. 9 depicts a cutaway view of an example window cassette and retaining clip.

FIG. 10 depicts an example panel formed using instructions from panel builder software.

FIGS. 11 and 12 are examples of mounting hardware.

FIG. 13 depicts a cutaway view of an example installed EIFS.

### DETAILED DESCRIPTION

The technology described in this disclosure relates to automating and simplifying the application of EIFS. As an example, the technology provides advantages by mapping the building to optimize material layout of large format foam insulation boards and robotically assisting workers in the scribing and installation processes. Further, the technology described herein includes using a mechanical fastening solution to remove installation temperature constraints, reduce cost, and reduce the time needed to fasten the foam insulation boards to the building. Additionally, the technology includes using a window cassette assembly to allow the installers to secure replacement windows from the exterior of the building, reducing the disturbance to building tenants and providing better energy efficiency than current window and/or sash retrofits.

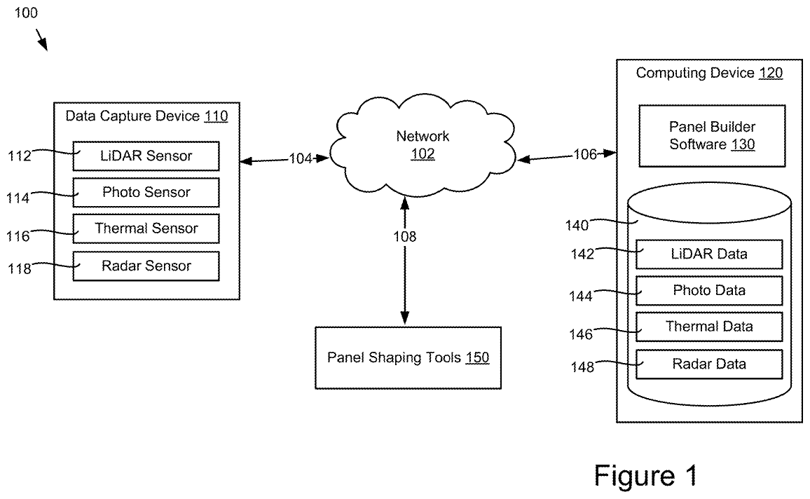

FIG. 1 is a block diagram illustrating an example system 100 for building EIFS panels. System 100 may include a data capture device 110, a computing device 120, and one or more panel shaping tools 150. The components of system 100 may be communicatively coupled via a network 102 for interaction with one another using standard networking protocols, as reflected by signal lines 104, 106, and 108. The components of system 100 will be explained in more detail with reference to the figures below.

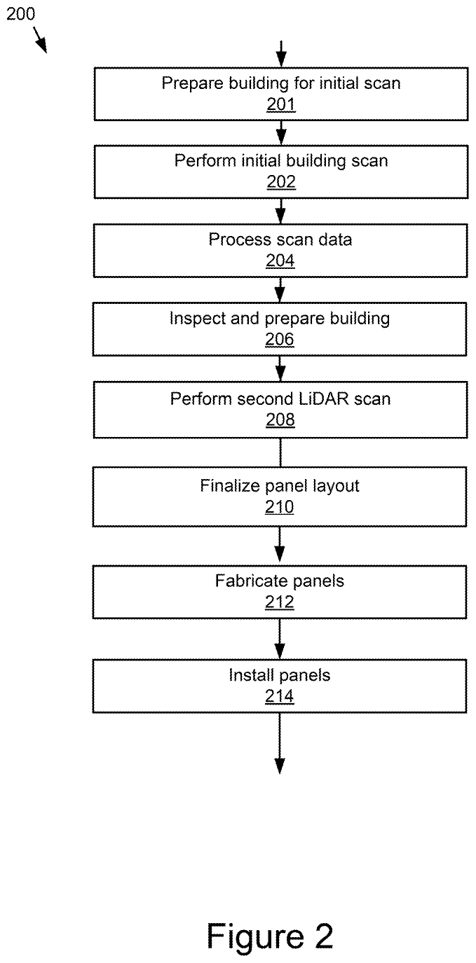

FIG. 2 is a flowchart of an example EIFS installation method 200 according to the techniques described herein. At 201, the building is prepared for the scan. In some embodiments, markers are placed on the building for referencing a location in the scan data and fixtures installed on the exterior of the building that could interfere with the building scan may be removed. At 202, data capture device 110 is used to perform an initial building scan. Data capture device 110 may be, for example, a robotic device with imaging capabilities, such as but not limited to a rig with sensors for LiDAR, photo, surface penetrating imaging (e.g., radar), and thermal imaging. As shown in the example of FIG. 1, data capture device 110 includes LiDAR sensor 112, photo sensor 114, thermal imaging sensor 116, and surface penetrating imaging sensor 118. The data capture device 110 captures structural information about the building that is needed for the EIFS installation. Advantageously, data capture device 110 can capture more data in less time than atypical building inspection by human assessment.

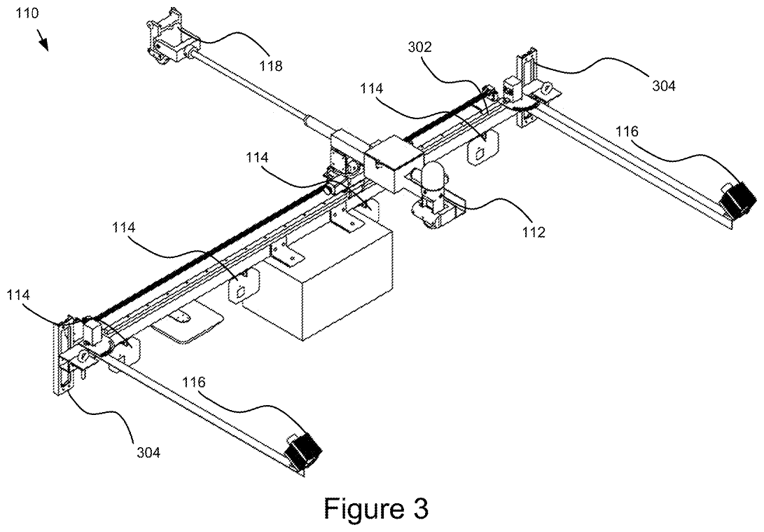

FIG. 3 depicts an example data capture device 110, according to one embodiment. The data capture device 110 comprises a frame 302 configured to carry one or more LiDAR sensors 112, photo sensors 114, thermal imaging sensor 116, and surface penetrating imaging sensors 118. In the example embodiment of FIG. 3, the data capture device 110 includes four photo sensors 114. Each phot sensor may be, for example, a motion-stabilized camera for capturing images of a building façade from multiple angles for developing a photogrammetric representation of the building for inspection and analysis of the facade. The surface penetrating imaging sensor 118 may be, for example, a ground penetrating radar (GPR) antenna configured to record data for developing a tomographic map of the building for inspection and analysis of the metal structures behind the facade. For instance, data capture device 110 is capable of capturing data revealing an internal structural support system behind the brick that support the existing brick cladding, which may include brick ties, relieving angles, lintels, etc., because this structural support system may be used to support the new exterior cladding. In the example of FIG. 3, the data capture device 110 includes two thermal imaging sensors 116. The thermal imaging sensor 116 may be, for example, high-resolution infrared cameras configured to record data for developing a visual heat map of the building for inspection and analysis of the facade. The LiDAR sensor 112 may be, for example, a 3D LiDAR scanner using simultaneous localization and mapping (SLAM) configured to record data for creating an accurate as-built model of the building for designing and engineering a new envelope for the EIFS installation.

The data capture device 110 is configured to be hoisted up and down in proximity to the building and can capture data using its sensors in a single pass. Remote control of the hoisting unit and the data capture device 110 may be controlled wirelessly, for example using a 2.4 GHz WiFi 5 protocol. Hoisting ropes are run through channels 304 in the frame 302 to stabilize the frame against wind.

Returning to the flowchart of FIG. 2, at 204, after the data has been gathered by the data capture device 110, the data can be transferred to computing device 120 for processing. While not depicted, the computing device 120 may include a (physical, virtual, etc.) processor, a non-transitory memory, a network interface, and a data store 140, which may be communicatively coupled by a communications bus. It should be understood that the computing device 120 may take other forms and include additional or fewer components without departing from the scope of the present disclosure. Computing device 120 may include a data store 140 configured to store the various data types collected by data capture device 110. For example, data store 140 may store LiDAR data 142, photo data 144, thermal data 146, and surface penetrating imaging data 148. Computing device 120 may also include panel builder module 130 configured to process the data stored in data store 140. The processed data will be used to design and engineer the new envelope and can be included as part of a building information package which can be referenced throughout the life of the building.

Software operating on the computing device 120 (e.g., the panel builder module 130, an operating system, device drivers, etc.) may cooperate and communicate via a software communication mechanism implemented. The software communication mechanism can include and/or facilitate, for example, inter-process communication, local function or procedure calls, remote procedure calls, an object broker, direct socket communication (e.g., TCP/IP sockets) among software modules, UDP broadcasts and receipts, HTTP connections, etc. Further, any or all of the communication could be secure (e.g., SSH, HTTPS, etc.). In addition, while a single computing device 120 is depicted in FIG. 1, it should be understood that one or more computing devices 120 may be used in implementing the techniques described herein.

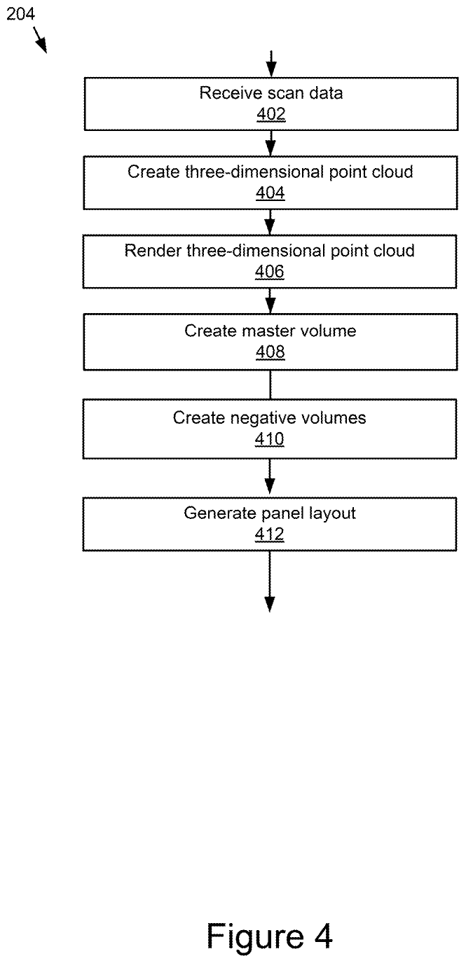

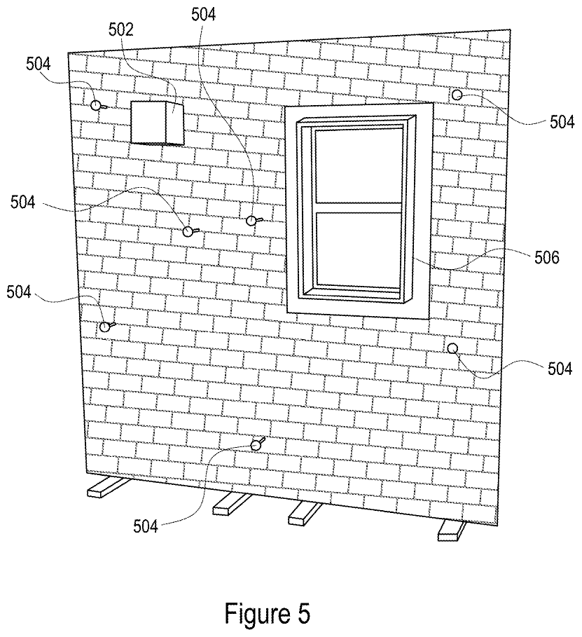

FIG. 4 is a flowchart of an example method 204 for processing scan data using panel builder module 130. The process as described below is for a single wall, for example, the wall depicted in the example of FIG. 5. However, it should be understood that the process may be repeated for each wall, or section of wall, for an EIFS installation project. At 402, panel builder module 130 receives scan data including, for example, LiDAR data 142, photo data 144, thermal data 146, and surface penetrating imaging data 148. At 404, panel builder module 130 uses LiDAR data 142 to create a three-dimensional point cloud or mesh file of the contours of the existing building façade. The result is a three-dimensional model of the building exterior which can be used by panel builder module 130 to create a map of the building to plan the layout of the foam panels as well as any repairs/modifications required to allow for panel installation.

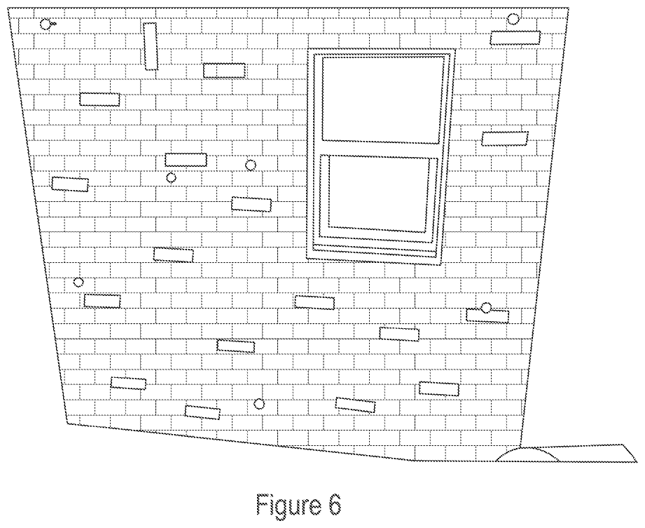

At 406, the three-dimensional point cloud or mesh file of the building is imported into the software and positioned in the coordinate system for measuring. In an example embodiment, panel builder module 130 may include a virtual reality engine that renders the three-dimensional point cloud so that personnel can use 3D visualization software and hardware, to view, manipulate, and edit the 3D models of the building and panels in three dimensions, as shown in the example of FIG. 6. For example, a technician can use virtual reality goggles to shape the mapping between the building and panels, and so forth. This workflow allows for faster rendering (by eliminating conversions between two and three-dimensional coordinate systems. In this 3D environment, a technician can take several measurements and check them against known actual measurements and adjust the scale of the rendered point cloud if necessary.

At 408, panel builder module 130 creates a master volume on the point cloud for creating the EIFS panel layout. In one embodiment, panel builder module 130 receives user input defining the boundary and thickness of the master volume based on interaction with the rendered 3D model of the building. In other embodiments, panel builder module 130 is configured to detect edges of walls and automatically generate the master volume. The initial master volume establishes the new building envelope in relation to the existing wall. The EIFS panels will be generated from this master volume.

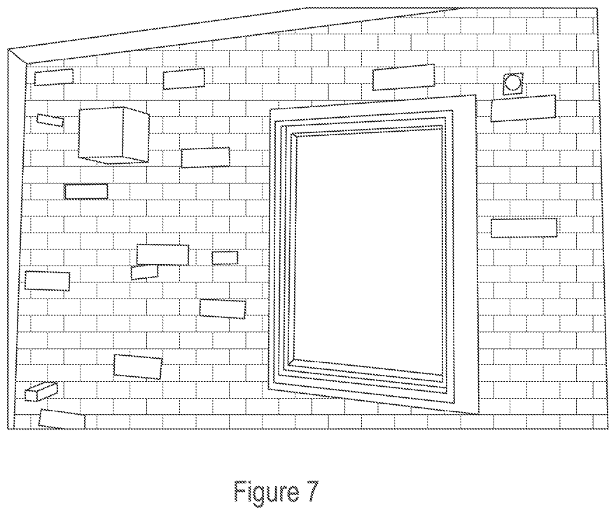

At 410, panel builder module 130 creates negative volumes corresponding to features on the 3D model of the building. For example, negative volumes may be created for objects that protrude through the panel (e.g., windows, utility connections, etc.) and for other features that do not protrude far enough to penetrate the exterior of a panel (e.g., conduits, surface details, locating pins, etc.), as shown in the example of FIG. 7. In one embodiment, panel builder module 130 receives user input defining the boundary and thickness of the negative volumes based on interaction with the rendered 3D model of the building. In other embodiments, panel builder module 130 is configured to detect features on the wall and automatically generate the negative volumes. The negative volumes are then subtracted from the master volume by panel builder module 130.

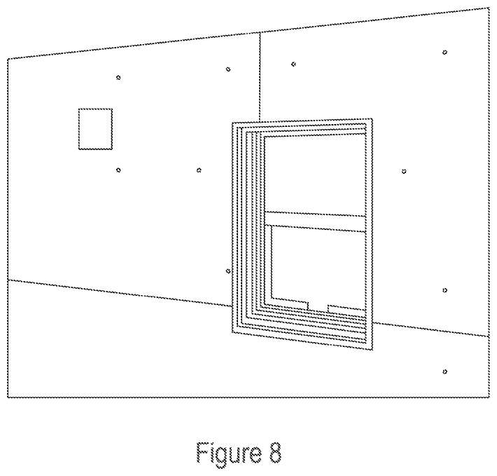

At 412, panel builder module 130 generates a panel layout on the master volume by running a routine that divides the master volume into one or more panels and determines the positions of panel fasteners and locating pins, as depicted in the example of FIG. 8. In some embodiments, panel builder module 130 allows a user to adjust panel sizes and seam locations for efficient use of material and to address building conditions and site restrictions.

Returning to FIG. 2, at 206, after panel builder module 130 has created a panel layout, the panel layout and the data collected by data capture device 110 can be used to inspect and prepare the building before the panels can be produced and attached. To prepare the building, features that protrude from the building might need to be removed. For example, window sills may have to be removed flush with the facade exterior to accommodate new window cassettes, as described below. Where fixtures need to be attached to the building (e.g., lights, utility connections, etc.) a mounting block 502 that will be flush with the envelope panel may be affixed to the existing facade. In one embodiment, the mounting block 502 is a high-density foam with thermal insulation properties similar to that of the EIFS panel that will accept mechanical fasteners and loads.

Panel locating node 504 may be installed to help locate the EIFS panels on the facade. In one embodiment, the locating node 504 may have a ball head and standoff from the wall. A recess in the back of the panel is created to mate with the locating node 504 thereby locating the panel on the wall. The ball head allows the locating node 504 to be mounted without concern for perpendicularity. In one embodiment, at least two pins are laid out on the wall per panel. These locating node 504 provide for the panels to be registered on the facade for proper installation and also act as a temporary panel support as the installer fastens the panels to the building.

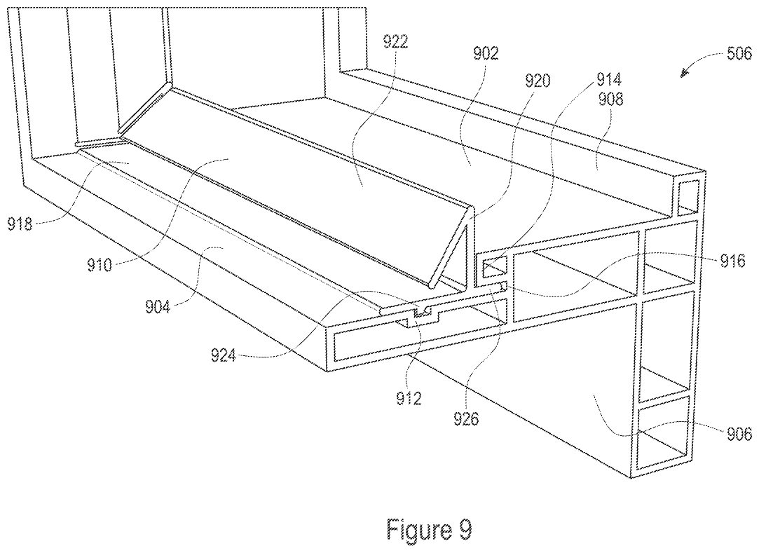

FIG. 9 depicts a cutaway view of an example window cassette 506. As depicted in the example of FIG. 9, a window cassette may include an inner cassette body 902, and outer cassette body 904, and a building connection flange 906. Window cassette 506, may be affixed to the exterior of the building using fasteners through building connection flange 906. The window cassette 506 is designed for a replacement window to be installed from the exterior of the building, thus minimizing disturbance to building tenants during an EIFS retrofit.

The inner cassette body 902, defines an opening into which a retrofit window can be installed. The inner cassette body 902 may include a stop 908 against which the interior surface of a replacement window unit (not shown) is placed when installed in the window cassette 506. In one embodiment, the stop 908 comprises a protrusion from the inner cassette body 902 that is positioned on the building side of the inner cassette body 902.

The outer cassette body 904 is coupled with a front side of the inner cassette body 902 and is configured to receive a retaining clip 910 that holds the window unit in the window cassette 506. To engage the retaining clip 910, the outer cassette body 904 includes a retaining clip securing channel 912 that runs along the interior surface of the outer cassette body 904 parallel to the window opening. Additionally, a protrusion 914 from the front of the inner cassette body 902 and the interior surface of the outer cassette body 904 define a retaining clip seating channel 916 to further engage the retaining clip 910.

Retaining clip 910 includes a bottom plate 918, a window retention member 920, a drip edge 922, a securing ridge 924, and a seating ridge 926. The bottom plate 918 is configured to rest on the interior surface of the outer cassette body 904 and the window retention member 920 protrudes substantially perpendicularly from the bottom plate 918 into the window opening beyond the interior surface of the inner cassette body 902. When a window unit is seated in the inner cassette body, the window retention member 920 secures the window unit against stop 908. To install the retaining clip 910, the seating ridge 926 is inserted into the retaining clip seating channel 916 and pressed inward until the securing ridge 924 engages with the retaining clip securing channel 912, locking the retaining clip 910 in place. Retaining clip 910 is simple to install, without tools, and creates a secure and clean finish to the exterior of the installed window. The retaining clip 910 may be mitered at the corners of the window cassette 506 to provide a finished surface against which another retaining clip can rest. As depicted in the example of FIG. 9, a typical window cassette will have four retaining clips 910 (one on the bottom, one on the top, and one on each side of the window opening) holding the window unit in the window cassette 506.

The drip edge 922 protrudes downward from the top of the window retention member 920 and creates a surface that directs water running down the window unit away from the base of the window unit to prevent water infiltration.

In some embodiments, one or more of the inner cassette body 902, the outer cassette body 904, and the building connection flange 906 may be filled with insulating foam to increase the overall insulation value and efficiency of the window cassette 506. In further embodiments, window cassette 506 can be sized so that the sash of the existing window can be removed, and the existing frame left in place. Sill and jamb trim can then be installed over the existing frame, eliminating the need to remove the old frame and avoiding potentially expensive asbestos remediation costs.

Using the window cassette approach, tenant disruption is minimal and only occurs during removal of the existing window and applying trim to the newly installed window cassette 506. Moreover, in addition to being structurally sound and externally installable without disruption to the interior of the building, the integration of the novel window cassettes 506 as described herein provides for thermal efficiency improvements of over 30% compared to existing solutions. This is due in part to the tight seal formed between the window cassette 506 and the precision-formed panels because of tight tolerances provided by the techniques described herein as compared to hand cut panels applied by construction workers under existing approaches which suffer from up to a 40% degradation in performance because of air infiltration at the window panel interface. Further, in climates that are more moderate and do not require the same thermal efficiency, the technology described herein can allow for the use of less expensive materials because the thermal performance is so much better (e.g., 5-inch foam thickness vs. 6-inch, less efficient foam material, etc.). Similar performance benefits were also discovered with respect to humidity/moisture management.

Returning to FIG. 2, at 208, a second LiDAR scan of the building may be performed by data capture device 110 account for the actual locations of the panel locating node 504, window cassettes 506 and mounting blocks installed after the first scan, and any other changes made to the building based on an analysis of the first scan. As described, the first scan is performed to prepare the project, create an initial panel layout and site plan, and create a bill of materials. The second scan is then performed to finalize the panel designs by adding additional scan data (e.g., to account for modifications to the building exterior as described above) to the first scan data. The second scan eliminates the need for precision installation of hardware because hardware can be installed “close enough” according to the initial design and the second scan provides the exact location of the hardware for use when creating the panels. This is advantageous because it creates flexibility at the installation site. In one embodiment, the second scan requires fewer data points since only the changes introduced by the installation of locating node 504 and window cassettes 506 are being accounted for. This means less processing and enough precision to allow the panel builder module 130 and the panel shaping tools 150 to communicate and fabricate the panels. While the process of creating panels is described with having two scans, in one embodiment, locating pins and window cassettes may be installed prior to the first scan and only a single scan is used by the panel builder module 130 to create the layout.

At 210, panel builder module 130 uses data from the first and second scans to finalize the panel layout. When the data from the second scan has been processed, the initial panel layout is modified to accommodate the actual location of the newly installed panel locating node 504 and window cassettes 506. Panel geometry will be finalized and 3D mesh files will be created for each panel with a map showing the location of each panel on the building. Any other fabrication or installation documents will be produced at the same time.

At 212, the panels are fabricated. To create the panels, panel builder module 130 generates code to control panel shaping tools 150 to shape the panels. In one embodiment, a computer numerical controlled (CNC) hot wire machine receives instructions from panel builder module 130 to cut panel perimeters and other features that extend through the panel (e.g., negative volumes for windows, doors, etc.). In some embodiments, the panels may be cut from a foam billet that is substantially thicker than the finished foam panels. Subsequently, a CNC milling machine may receive instructions from panel builder module 130 to mill the back side of the panels.

As each panel is formed for a particular portion of the building facade, and the location of the internal structural members of the building are advantageously pre-determined by the scanning as described herein, the panels may be formed with fastener holes in precise locations that match the internal structural members. Fastener anchors may be easily inserted into the preformed holes and the panels can be affixed to the structural members through the existing building facade using fasteners. This process eliminates the manual work involved by workers to try and locate the right place in which to apply a fastener, and thus speeds up the entire retrofit project. It also eliminates the situation where fasters are only drilled into the facade and not the internal structure (which can lead to dangerous cladding failures and brick falls).

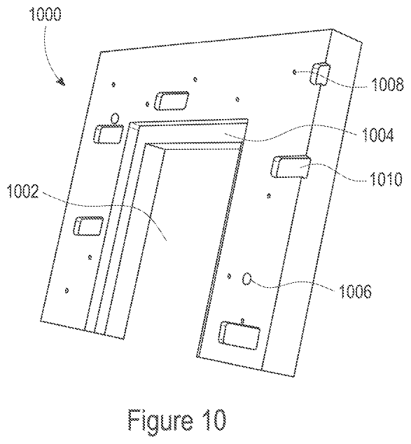

FIG. 10 depicts an example panel 1000 formed using instructions from panel builder module 130. In one embodiment, the foam body of panel 1000 can be formed from six inch thick graphite enhance polystyrene (GPS). In other embodiments, other polystyrene or similar foam panels can be used. While EIFS panels used in the process described herein may vary in size, based on the panel layout determined by panel builder module 130, the dimensions of an EIFS panel may, in some embodiments, be as large as 4′ (tall)×12′ (long)×6″ (thick). The larger format of the EIFS panels according to the techniques described herein reduce installation cost because fewer panels have to be prepared, transported to, and affixed to the building exterior. Additionally, the thicker panels with fewer seams can lead to better thermal performance of the building envelope. The larger boards can result in a 50% reduction in seams, reducing the potential for air and moisture infiltration resulting in a more airtight building with fewer moisture and mold issues.

As can be seen in the example of FIG. 10, the panel includes a void 1002 cut out for a window, a recess 1004 milled to fit over the building connection flange 906 of a window cassette 506. This configuration of panel 1000 and window cassette 506 provides very little thermal loss at the window perimeter compared to existing solutions. This is due to the relatively low thermal conductivity of the vinyl used in constructing the window cassette 506, and the location of window unit in the window cassette 506 being more in-line with the surrounding panel 1000.

To secure the panel 1000 to the exterior wall of a building, the panel includes a recess 1006 for coupling with a locating node 504 and a pre-drilled fastener hole 1008 for an anchor and/or fastener. As described elsewhere herein, panel builder module 130 may determine where building support structures are located and position fastener holes such that when panel 1000 is positioned on the exterior wall of a building, the fastener hole 1008 aligns with the building structure. This allows the fastener to be inserted into the building structure rather than just the cladding of the building providing for a more secure attachment of panel 1000. To align the fastener hole 1008 with the building structure, panel builder module 130 places the fastener hole 1008 relative to the recess 1006 such that when the locating node 504 is coupled with recess 1006, the fastener hole is correctly aligned with the building structure.

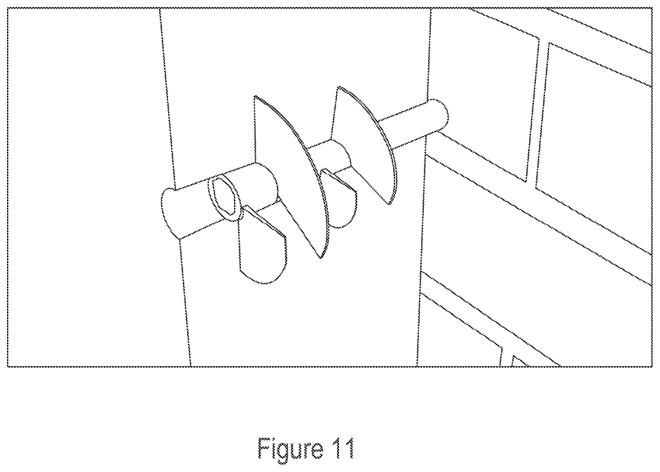

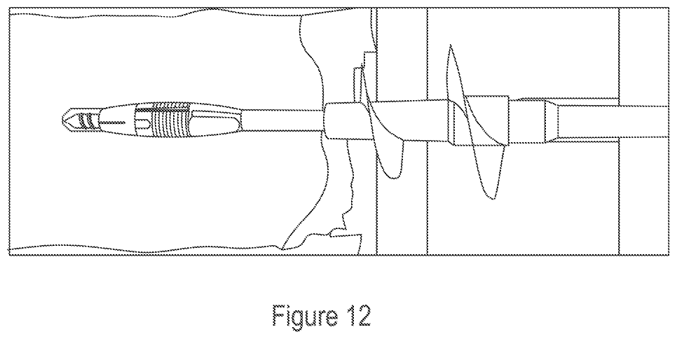

In some embodiments, as part of the panel fabrication process, fastener hardware, such as the auger style anchor depicted in the examples of FIGS. 11 and 12 are installed in the pre-drilled fastener hole 1008 of panel 1000. Further, the fasteners can, in some embodiments, be embedded on the backside of the panel prior to install, which eliminates workers from having to handle the fasteners and just having to drill and fasten the anchor portion of the fastener into the existing structure. In yet another embodiment, a locating node 504 can double as a connection point to the building by having a securing mechanism (not shown) placed on the building side of panel 1000 that engages with locating node 504 to secure the panel to the building and removing the need for additional fasteners to be used.

In addition to recess 1006, panel builder module 130 defines recesses, such as recess 1010, to be fabricated into the building facing side of panel 1000 to fit over features of the exterior wall of the building.

Returning to FIG. 2, at 214, the panels can be installed on the existing building facade. When a panel is completed, it may bundled in order with other panels and lifted to the roof of the building for staging. Panels are then lowered into position one at a time to meet the installer at the panel location specified by the panel layout map. The installer then positions the panel with the aid of the previously installed panel locating node 504. Once located, holes are drilled into the building structure through the pre-installed mounting hardware and mechanical fasteners are used to fasten the panel to the wall. This system provides a means of delivering the panels to the installer just as needed rather than interrupting the workflow when the installer needs to resupply. It will also allow the roof to be used as a staging area where space around buildings is limited.

Once the panels have been secured, windows can be installed and the exterior finish applied. As described above, the design of the window cassette 506 provides for snap-in installation of the window unit from the exterior of the building. While window installation may be ordered as a last step, the windows can be installed at any time convenient to the process after the installation of the window cassette 506. This is especially important as window lead times can vary. The interior sill and jams can be installed at any time after the window cassette 506 is fastened to the building exterior. Interior sill and jam installation is the only work that will impact the tenant, this work does not hold up any of the other system work, and can be scheduled throughout the project to meet a time convenient to the tenant.

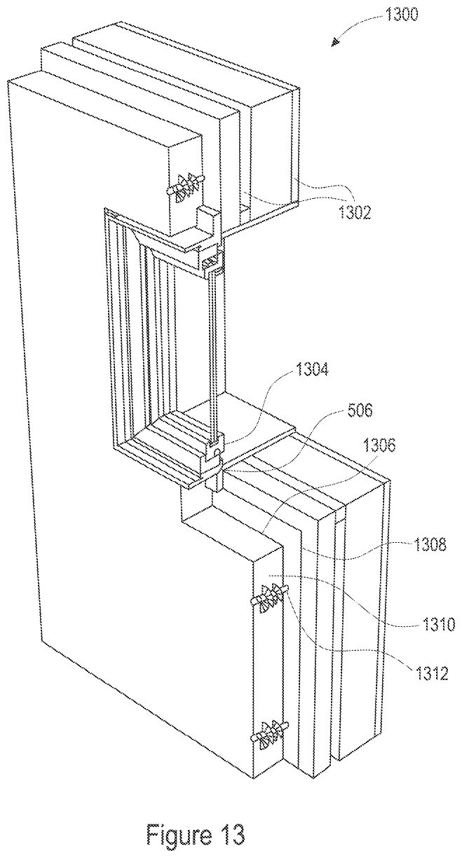

FIG. 13 depicts a cutaway view of an example installed EIFS 1300. As depicted in the example of FIG. 13, the existing wall assembly 1302 includes a masonry veneer, air cavity, structural backup wall, and plaster or board interior finish. A window unit 1304 is installed in window cassette 506. In some embodiments, drainage grooves 1306 are milled into the back of the EIFS panel 1310 and an air-water vapor control layer 1308 may be installed to regulate moisture transfer. The EIFS panel 1310 is affixed to the existing wall assembly 1302 by anchor 1312.

The foregoing description, for purpose of explanation, has been described with reference to various embodiments and examples. However, the illustrative discussions above are not intended to be exhaustive or to limit the invention to the precise forms disclosed. Many modifications and variations are possible in view of the above teachings. The various embodiments and examples were chosen and described in order to best explain the principles of the invention and its practical applications, to thereby enable others skilled in the art to utilize the innovative technology with various modifications as may be suited to the particular use contemplated. For instance, it should be understood that the technology described herein can be practiced without these specific details in some cases. Further, various systems, devices, and structures are shown in block diagram form in order to avoid obscuring the description. For instance, various implementations are described as having particular hardware, software, and user interfaces. However, the present disclosure applies to any type of computing device that can receive data and commands, and to any peripheral devices providing services.

In some instances, various implementations may be presented herein in terms of algorithms and symbolic representations of operations on data bits within a computer memory. An algorithm is here, and generally, conceived to be a self-consistent set of operations leading to a desired result. The operations are those requiring physical manipulations of physical quantities. Usually, though not necessarily, these quantities take the form of electrical or magnetic signals capable of being stored, transferred, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. Unless specifically stated otherwise as apparent from the following discussion, it is appreciated that throughout this disclosure, discussions utilizing terms such as “processing,” “computing,” “calculating,” “determining,” “displaying,” or the like, refer to the action and methods of a computer system that manipulates and transforms data represented as physical (electronic) quantities within the computer system's registers and memories into other data similarly represented as physical quantities within the computer system memories or registers or other such information storage, transmission or display devices.

A data processing system suitable for storing and/or executing program code, such as the computing system and/or devices discussed herein, may include at least one processor coupled directly or indirectly to memory elements through a system bus. The memory elements can include local memory employed during actual execution of the program code, bulk storage, and cache memories that provide temporary storage of at least some program code in order to reduce the number of times code must be retrieved from bulk storage during execution. Input or I/O devices can be coupled to the system either directly or through intervening I/O controllers. The data processing system may include an apparatus may be specially constructed for the required purposes, or it may comprise a general-purpose computer selectively activated or reconfigured by a computer program stored in the computer.

The foregoing description has been presented for the purposes of illustration and description. It is not intended to be exhaustive or to limit the specification to the precise form disclosed. Many modifications and variations are possible in light of the above teaching. It is intended that the scope of the disclosure be limited not by this detailed description, but rather by the claims of this application. As will be understood by those familiar with the art, the specification may be embodied in other specific forms without departing from the spirit or essential characteristics thereof. Likewise, the particular naming and division of the modules, routines, features, attributes, methodologies and other aspects may not be mandatory or significant, and the mechanisms that implement the specification or its features may have different names, divisions, and/or formats.

Furthermore, the modules, routines, features, attributes, methodologies and other aspects of the disclosure can be implemented as software, hardware, firmware, or any combination of the foregoing. The technology can also take the form of a computer program product accessible from a computer-usable or computer-readable medium providing program code for use by or in connection with a computer or any instruction execution system. Wherever a component, an example of which is a module or engine, of the specification is implemented as software, the component can be implemented as a standalone program, as part of a larger program, as a plurality of separate programs, as a statically or dynamically linked library, as a kernel loadable module, as firmware, as resident software, as microcode, as a device driver, and/or in every and any other way known now or in the future. Additionally, the disclosure is in no way limited to implementation in any specific programming language, or for any specific operating system or environment. Accordingly, the disclosure is intended to be illustrative, but not limiting, of the scope of the subject matter set forth in the following claims.

What is claimed is:

1. A window cassette comprising:
an inner cassette body, the inner cassette body defining an opening configured to receive a window unit;
a stop positioned around an interior surface of the inner cassette body on a building side of the window cassette, the stop configured to abut an interior surface of the window unit placed in the inner cassette body from an exterior side;
an outer cassette body coupled with a front side of the inner cassette body, the outer cassette body configured to receive a retaining clip, the retaining clip configured to hold the window unit in the inner cassette body against the stop; and
a building connection flange positioned around an exterior surface of the inner cassette body, the building connection flange configured to allow the window cassette to be affixed to a building exterior.

2. The window cassette of claim 1, further comprising:
a retaining clip seating channel defined by a protrusion from the front side of the inner cassette body and an interior surface of the outer cassette body; and
a retaining clip securing channel on an interior surface of the outer cassette body.

3. The window cassette of claim 2, wherein the retaining clip further comprises:
a bottom plate, the bottom plate configured to fit in the interior surface of the outer cassette body having a securing ridge configured to couple with the retaining clip securing channel;
a window retention member protruding from a top side of the bottom plate and configured to extend beyond the interior surface of the inner cassette body to retain the window unit in the window cassette; and
a seating ridge protruding from the bottom plate and configured to couple with the retaining clip seating channel.

4. The window cassette of claim 3, wherein the retaining clip further comprises:
a drip edge coupled with the window retention member, the drip edge configured to direct water away from the window unit.

5. The window cassette of claim 1, wherein the inner cassette body, the building connection flange, and the outer cassette body are filled with insulating foam.

6. The window cassette of claim 1, wherein the retaining clip comprises a mitered edge.

7. A method comprising:
performing, by a data capture device, a first scan of an exterior wall of a building;
processing, by a panel builder module, first scan data from the data capture device to generate a first panel layout;
performing, by the data capture device, a second scan of the exterior wall of the building, the second scan performed to capture data reflecting modifications made to the exterior wall of the building based on analysis of the first scan;
creating, by the panel builder module, a second panel layout, the second panel layout including a second plurality of negative volumes based on the first scan and the second scan; and
fabricating, by a panel shaping tool, an EIFS panel based on the second panel layout.

8. The method of claim 7, wherein the data capture device comprises a plurality of sensors.

9. The method of claim 8, wherein the plurality of sensors include a LiDAR sensor, a photo sensor, a thermal imaging sensor, and a surface penetrating imaging sensor.

10. The method of claim 7, wherein processing the first scan data further comprises:
creating, by the panel builder module, a three-dimensional point cloud of the exterior wall of the building using the first scan data;
rendering, by the panel builder module, a model of the exterior wall of the building using the three-dimensional point cloud;
creating, by the panel builder module, a master volume for creating the first panel layout;
creating, by the panel builder module, a first plurality of negative volumes in the master volume corresponding to features of the exterior wall of the building; and
generating, by the panel builder module, the first panel layout on the master volume.

11. The method of claim 10, wherein creating the second panel layout comprises:
identifying, by the panel builder module, a location of a locating pin installed on the exterior wall of the building;
identifying, by the panel builder module, a location of a window cassette installed on the exterior wall of the building; and
creating, by the panel builder module, the second plurality of negative volumes corresponding to the location of the locating pin and the location of the window cassette.

12. The method of claim 11, wherein fabricating the EIFS panel comprises:
cutting, by the panel shaping tool, the EIFS panel from a foam billet; and
cutting, by the panel shaping tool, a plurality of voids and a plurality of recesses in the EIFS panel based on the first plurality of negative volumes and the second plurality of negative volumes.

13. The method of claim 11, further comprising:
fastening the EIFS panel to the exterior wall of the building by:
aligning a recess corresponding to the locating pin with the locating pin;
drilling a hole in the exterior wall of the building through a pre-drilled fastener hole in the EIFS panel; and
securing the EIFS panel to the exterior wall of the building with a fastener inserted through the pre-drilled fastener hole.

14. An EIFS panel comprising:
a foam body;
a pre-drilled fastener hole extending through the foam body, the pre-drilled fastener hole configured to align a fastener with a support structure of a building, wherein, when the fastener is inserted through the pre-drilled fastener hole, the EIFS panel is secured to the support structure of the building; and
a first recess in a building facing surface of the foam body, the first recess configured to couple with a locating node affixed to an exterior wall of a building, wherein coupling the first recess and the locating node aligns the pre-drilled fastener hole with the support structure of the building and supports the foam body while the fastener is attached to the support structure of the building.

15. The EIFS panel of claim 14, further comprising:
a second recess in the building facing surface of the foam body, the second recess configured to align with a feature on the exterior wall of the building, such that the foam body sits flush with the exterior wall of the building.

16. The EIFS panel of claim 14, further comprising:
a first void cut through the foam body, the first void configured to align with a window cassette attached to the exterior wall of the building; and
a third recess in the building facing surface of the foam body surrounding the first void, the third recess configured to fit over a flange of the window cassette.

17. The EIFS panel of claim 14, further comprising:
a drainage groove in the building facing surface of the foam body.

18. The EIFS panel of claim 14, further comprising:
a foam attachment anchor secured in the pre-drilled fastener hole, the foam attachment anchor configured to couple the fastener with the foam body.

19. The EIFS panel of claim 14, further comprising:
a second void cut through the foam body, the second void configured to align with a mounting block attached to the exterior wall of the building.

20. The EIFS panel of claim 14, wherein the foam body comprises a graphite enhanced polystyrene insulation board.
